(19) United States
(12) Patent Application Publication
(10) Pub. No.: US 2016/0111473 A1
(43) Pub. Date: Apr. 21, 2016

(54) ORGANIC PHOTODIODES, ORGANIC X-RAY DETECTORS AND X-RAY SYSTEMS

(71) Applicant: General Electric Company, Schenectady, NY (US)

(72) Inventors: Jie Jerry Liu, Niskayuna, NY (US); Kwang Hyup An, Rexford, NY (US); Gautam Parthasarathy, Niskayuna, NY (US)

(21) Appl. No.: 14/517,214

(22) Filed: Oct. 17, 2014

(51) Int. Cl. H01L 27/30; H01L 51/00; G01T 1/24; H01L 51/44

(52) U.S. Cl. CPC H01L 27/308; H01L 27/307; H01L 51/442; H01L 51/0021; G01T 1/248; H01L 2251/305; H01L 2251/301

(57) ABSTRACT

An organic photodiode is presented. The organic photodiode includes a first electrode; an organic absorber layer disposed on the first electrode; a second electrode disposed on the organic absorber layer; and a first charge blocking layer including a metal fluoride disposed between the organic absorber layer and one of the first electrode or the second electrode. The metal fluoride comprises lithium, sodium, potassium, rubidium, cesium, berrylium, magnesium, calcium, strontium, barium, iron, yttrium, ytterbium, or combinations thereof. The charge blocking layer is substantially free of an electrically conductive material, and the thickness of the charge blocking layer is greater than about 10 nanometers. A method of making an organic photodiode and an organic x-ray detector are also presented.

### BACKGROUND

Embodiments of the invention generally relate to organic photodiodes and organic x-ray detectors. More particularly, embodiments of the invention relate to organic photodiodes and organic x-ray detectors including charge blocking layers.

Digital x-ray detectors fabricated with continuous photodiodes have potential applications for low cost digital radiography as well as for rugged, light-weight and portable detectors. Digital x-ray detectors with continuous photodiodes have an increased fill factor and potentially higher quantum efficiency. The continuous photodiode generally includes organic photodiodes (OPDs).

Single-layered OPDs are attractive because of their simplified device structure and potentially low manufacturing cost. However, the single-layered OPDs generally have high dark leakage currents and poor stability against exposure to moisture and oxygen. One approach for reducing the dark leakage current is to incorporate one or two blocking layers that separate the active absorber from one or both electrodes. Fullerenes, polyvinylcarbazoles, and polystyrene-amine copolymer are some of the materials that have been used in these layers

There is a continuing need for improved organic photodiodes and organic x-ray detector configurations.

### BRIEF DESCRIPTION

In one aspect, the invention relates to an organic photodiode including a first electrode; an organic absorber layer disposed on the first electrode; a second electrode disposed on the organic absorber layer; and a first charge blocking layer including a metal fluoride disposed between the organic absorber layer and one of the first electrode or the second electrode. The metal fluoride includes lithium, sodium, potassium, rubidium, cesium, beryllium, magnesium, calcium, strontium, barium, iron, yttrium, ytterbium, or combinations thereof. The charge blocking layer is substantially free of an electrically conductive material, and the thickness of the charge blocking layer is greater than about 10 nanometers.

In another aspect, the invention relates to a method of forming an organic photodiode. The method includes disposing an organic absorber layer on a first electrode; disposing a second electrode on the organic absorber layer; and disposing a first charge blocking layer comprising a metal fluoride between the organic absorber layer and one of the first electrode or the second electrode. The metal fluoride includes lithium, sodium, potassium, rubidium, cesium, beryllium, magnesium, calcium, strontium, barium, iron, yttrium, ytterbium, or combinations thereof. The charge blocking layer is substantially free of an electrically conductive material, and the thickness of the charge blocking layer is greater than about 10 nanometers.

In yet another aspect, the invention relates to an organic x-ray detector, including a thin-film transistor (TFT) array disposed on a substrate; an organic photodiode disposed on the TFT array, and a scintillator layer disposed on the organic photodiode. The organic photodiode includes a first electrode; an organic absorber layer disposed on the first electrode; a second electrode disposed on the organic absorber layer; and a first charge blocking layer including a metal fluoride disposed between the organic absorber layer and one of the first electrode or the second electrode. The metal fluoride includes lithium, sodium, potassium, rubidium, cesium, beryllium, magnesium, calcium, strontium, barium, iron, yttrium, ytterbium, or combinations thereof. The charge blocking layer is substantially free of an electrically conductive material, and the thickness of the charge blocking layer is greater than about 10 nanometers.

These and other features, embodiments, and advantages of the present invention may be understood more readily by reference to the following detailed description.

### DRAWINGS

These and other features, aspects, and advantages of the present invention will become better understood when the following detailed description is read with reference to the accompanying drawings, wherein:

FIG. 1 is a schematic of an organic photodiode, according to one embodiment of the invention;

FIG. 2 is a schematic of an organic photodiode, according to one embodiment of the invention;

FIG. 3 is a schematic of an organic photodiode, according to one embodiment of the invention;

FIG. 4 is a schematic of an organic photodiode, according to one embodiment of the invention;

FIG. 5 is a schematic of an organic x-ray detector, according to one embodiment of the invention;

FIG. 6 is a schematic of an organic x-ray detector, according to one embodiment of the invention;

FIG. 7 is a schematic of an organic x-ray detector, according to one embodiment of the invention;

FIG. 8 is a schematic of an organic x-ray detector, according to one embodiment of the invention;

FIG. 9 is schematic of an x-ray system, according to one embodiment of the invention;

FIG. 10A is schematic of an x-ray system, according to one embodiment of the invention;

FIG. 10B is schematic of an x-ray system, according to one embodiment of the invention;

FIG. 11 shows the dark current measurements for an organic photodiode, according to one embodiment of the invention;

FIG. 12 shows the dark current measurements for an organic photodiode, according to one embodiment of the invention;

FIG. 13 shows the dark current measurements for an organic photodiode, according to one embodiment of the invention; and

FIG. 14 shows the defect maps of the organic x-ray detectors, according to some embodiments of the invention.

### DETAILED DESCRIPTION

In the following specification and the claims, which follow, reference will be made to a number of terms, which shall be defined to have the following meanings. The singular forms “a”, “an” and “the” include plural referents unless the context clearly dictates otherwise. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, and “substantially” is not to be limited to the precise value specified. In some instances, the approximating language may correspond to the precision of an instrument for measuring the value. Similarly, “free” may be used in combination with a term, and may include an insubstantial number, or trace amounts, while still being considered free of the modified term. Here and throughout the specification and claims, range limitations may be combined and/or interchanged, such ranges are identified and include all the sub-ranges contained therein unless context or language indicates otherwise.

As used herein, the term “layer” refers to a material disposed on at least a portion of an underlying surface in a continuous or discontinuous manner. Further, the term “layer” does not necessarily mean a uniform thickness of the disposed material, and the disposed material may have a uniform or a variable thickness. As used herein, the term “disposed on” refers to layers disposed directly in contact with each other or indirectly by having intervening layers there between, unless otherwise specifically indicated. The term “adjacent” as used herein means that the two layers are disposed contiguously and are in direct contact with each other.

In the present disclosure, when a layer is being described as “on” another layer or substrate, it is to be understood that the layers can either be directly contacting each other or have one (or more) layer or feature between the layers. Further, the term “on” describes the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated.

Electro-optical devices, such as, but not limited to, organic x-ray detectors include an electronically or optically active portion—e.g., scintillators and photodiodes that are frequently disposed on a substrate. In order to protect the active portion and the substrate from degradation due to exposure to moisture, oxygen, or corrosive chemical attack, the electro-optical devices may be encased. Some x-ray detectors include a top cover along with edge seals. However, edge sealants are generally more permeable for moisture and oxygen than the top cover, and edge ingress of moisture/oxygen may be a limiting factor for long-term stability.

One aspect of the invention is to provide an organic photodiode that may be employed in electro-optical devices, such as, but not limited to, organic x-ray detectors. The organic photodiode including a first electrode; an organic absorber layer disposed on the first electrode; a second electrode disposed on the organic absorber layer; and a first charge blocking layer including a metal fluoride disposed between the organic absorber layer and one of the first electrode or the second electrode. The metal fluoride includes lithium, sodium, potassium, rubidium, cesium, beryllium, magnesium, calcium, strontium, barium, iron, yttrium, ytterbium, or combinations thereof. The charge blocking layer is substantially free of an electrically conductive material, and the thickness of the charge blocking layer is greater than about 10 nanometers.

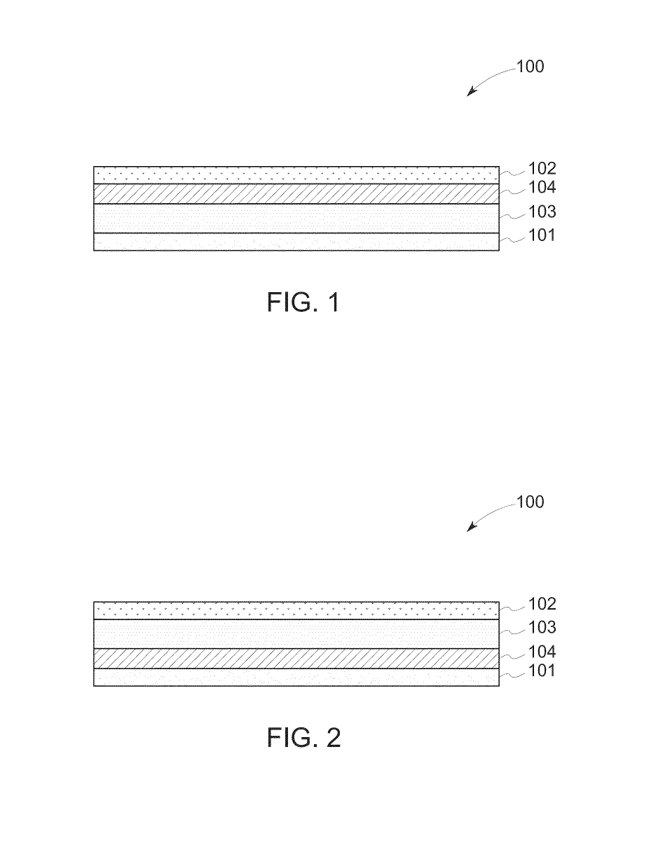

A schematic representation of such an organic photodiode (OPD) is shown in FIGS. 1-4. As shown in FIGS. 1-4, an organic photodiode 100 includes a first electrode 101, a second electrode 102, and an absorber layer (sometimes also referred to as an “active layer”) 103 interposed between the first electrode 101 and the second electrode 102.

Depending on the application and variations in design, the organic photodiode 100 may include a single absorber layer or may include multiple absorber layers. The organic absorber layer may be a bulk, hetero-junction organic photodiode layer that absorbs light, separates charge and transports holes and electrons to the contact layers. In some embodiments, the absorber may be patterned. Absorber layer may include a blend of a donor material and an acceptor material; more than one donor or acceptor may be included in the blend. In some embodiments, the donor and acceptor may be incorporated in the same molecule. Further, the HOMO/LUMO levels of the donor and acceptor materials may be compatible with that of the first and second electrodes in order to allow efficient charge extraction without creating an energetic barrier.

Suitable donor materials include low bandgap polymers having LUMO ranging from about 1.9 eV to about 4.9 eV, particularly from 2.5 eV to 4.5 eV, more particularly from 3.0 eV to 4.5 eV; and HOMO ranging from about 2.9 eV to about 7 eV, particularly from 4.0 eV to 6 eV, more particularly from 4.5 eV to 6 eV. The low band gap polymers include conjugated polymers and copolymers composed of units derived from substituted or unsubstituted monoheterocyclic and polyheterocyclic monomers such as thiophene, fluorene, phenylenvinylene, carbazole, pyrrolopyrrole, and fused heteropolycyclic monomers containing the thiophene ring, including, but not limited to, thienothiophene, benzodithiophene, benzothiadiazole, pyrrolothiophene monomers, and substituted analogs thereof. In particular embodiments, the low band gap polymers comprise units derived from substituted or unsubstituted thienothiophene, benzodithiophene, benzothiadiazole, carbazole, isothianaphthene, pyrrole, benzo-bis(thiadiazole), thienopyrazine, fluorene, thiadiazolequinoxaline, or combinations thereof. In the context of the low band gap polymers described herein, the term “units derived from” means that the units are each a residue comprising the monoheterocyclic and polyheterocyclic group, without regard to the substituents present before or during the polymerization; for example, “the low band gap polymers comprise units derived from thienothiophene” means that the low band gap polymers comprise divalent thienothiophenyl groups. Examples of suitable materials for use as low bandgap polymers in the organic x-ray detectors according to the present invention include copolymers derived from substituted or unsubstituted thienothiophene, benzodithiophene, benzothiadiazole or carbazole monomers, and combinations thereof, such as poly[[4,8-bis[(2-ethyl hexyl)oxy]benzo[1,2-b:4,5-b′]dithiophene-2,6-diyl][3-fluoro-2-[(2-ethylhexyl)carbonyl]thieno[3,4-b]thiophenediyl (PTB7), 2,1,3-benzothiadiazole-4,7-diyl[4,4-bis(2-ethylhexyl)-4H-cyclopenta[2,1-b:3,4-b′]dithiophene-2,6-diyl (PCPDTBT), poly[[9-(1-octylnonyl)-9H-carbazole-2,7-diyl]-2,5-thiophenediyl-2,1,3-benzothiadiazole-4,7-diyl-2,5-thiophenediyl] (PCDTBT), poly[(4,40-bis(2-ethylhexyl)dithieno[3,2-b:20,30-d]silole)-2,6-diyl-alt-(2,1,3-benzo-thiadiazole)-4,7-diyl] (PSBTBT), poly((4,8-bis(octyloxy)benzo(1,2-b:4,5-b′)dithiophene-2,6-diyl)(2-((dodecyloxy)carbonyl)thieno(3,4-b)thiophenediyl)) (PTB1), poly((4,8-bis(octyloxy)benzo(1,2-b:4,5-b′)dithiophene-2,6-diyl)(2-((ethylhexyloxy)carbonyl)thieno(3,4-b)thiophenediyl)) (PTB2), poly((4,8-bis(octyl)benzo(1,2-b:4,5-b′)dithiophene-2,6-diyl) (2-((ethylhexyloxy)carbonyl)thieno(3,4-b)thiophenediyl)) (PTB3), poly((4,8-bis-(ethylhexyloxybenzo(1,2-b:4,5-b′)dithiophene-2,6-diyl)(2-((octyloxy)carbonyl)-3-fluoro)thieno(3,4-b)thiophenediyl)) (PTB4), poly((4,8-bis(ethylhexyloxybenzo(1,2-b:4,5-b′)dithiophene-2,6-diyl)(2-((octyloxy)carbonyl)thieno(3,4-b)thiophenediyl)) (PTB5), poly((4,8-bis(octyloxy)benzo(1,2-b:4,5-b′)dithiophene-2,6-diyl)(2-((butyloctyloxy)carbonyl)thieno(3,4-b)thiophenediyl)) (PTB6), poly[[5-(2-ethylhexyl)-5,6-dihydro-4,6-dioxo-4H-thieno[3,4-c]pyrrole-1,3-diyl][4,8-bis[(2-ethylhexyl)oxy]benzo[1,2-b:4,5-b′]dithiophene-2,6-diyl]] (PBDTTPD), poly[1-(6-{4,8-bis[(2-ethylhexyl)oxy]-6-methylbenzo[1,2-b:4,5-b′]dithiophen-2-yl}-3-fluoro-4-methylthieno[3,4-b]thiophen-2-yl)-1-octanone] (PBDTTT-CF), and poly[2,1,3-benzothiadiazole-4,7-diyl-2,5-thiophenediyl(9,9-dioctyl-9H-9-silafluorene-2,7-diyl)-2,5-thiophenediyl] (PSiF-DBT). Other suitable materials are poly[5,7-bis(4-decanyl-2-thienyl)thieno[3,4-b]diathiazole-thiophene-2,5] (PDDTT), poly[2,3-bis(4-(2-ethylhexyloxy)phenyl)-5,7-di(thiophen-2-yl)thieno[3,4-b]pyrazine] (PDTTP), and polythieno[3,4-b]thiophene (PTT). In particular embodiments, suitable materials are copolymers derived from substituted or unsubstituted benzodithiophene monomers, such as the PTB1-7 series and PCPDTBT; or benzothiadiazole monomers, such as PCDTBT and PCPDTBT.

In particular embodiments, the donor material is a polymer with a low degree of crystallinity or is an amorphous polymer. Degree of crystallinity may be increased by substituting aromatic rings of the main polymer chain. Long chain alkyl groups containing six or more carbons or bulky polyhedral oligosilsesquioxane (POSS) may result in a polymer material with a lower degree of crystallinity than a polymer having no substituents on the aromatic ring, or having short chain substituents such as methyl groups. Degree of crystallinity may also be influenced by processing conditions and means, including, but not limited to, the solvents used to process the material and thermal annealing conditions. Degree of crystallinity is readily determined using analytical techniques such as calorimetry, differential scanning calorimetry, x-ray diffraction, infrared spectroscopy and polarized light microscopy.

Suitable materials for the acceptor include fullerene derivatives such as [6,6]-phenyl-C₆₁-butyric acid methyl ester (PCBM), PCBM analogs such as PC₇₀BM, PC₇₁BM, PC₈₀BM, bis-adducts thereof, such as bis-PC₇₁BM, indene mono-adducts thereof, such as indene-C₆₀ monoadduct (ICMA) and indene bis-adducts thereof, such as indene-C₆₀ bisadduct (ICBA). Fluorene copolymers such as poly[(9,9-dioctylfluorenyl-2,7-diyl)-alt-(4,7-bis(3-hexylthiophen-5-yl)-2,1,3-benzothiadiazole)-2′,2″-diyl] (F8TBT) may also be used, alone or with a fullerene derivative.

In one embodiment, the first electrode 101 functions as the cathode and the second electrode 102 as the anode. In another embodiment, the first electrode 101 functions as the anode and the second electrode 102 as the cathode. Suitable anode materials include, but are not limited to, metals such as Al, Ag, Au, and Pt, metal oxides such as indium tin oxide (ITO), indium zinc oxide (IZO), and zinc oxide (ZnO), and organic conductors such as p-doped conjugated polymers like PEDOT.

Suitable cathode materials include substantially transparent conductive oxides (TCO) and thin films of metals such as alkali metals, alkaline earth metals, aluminum, gold and silver. In certain embodiments, the cathode material includes sputtered substantially transparent conductive oxides (TCO). Examples of suitable TCOs include ITO, IZO, aluminum zinc oxide (AZO), fluorinated tin oxide (FTO), tin oxide (SnO₂), titanium dioxide (TiO₂), ZnO, indium zinc oxide (In—Zn—O series), indium gallium oxide, gallium zinc oxide, indium silicon zinc oxide, indium gallium zinc oxide, or combinations thereof.

As noted earlier, the organic photodiode 100 further includes a first charge blocking layer 104 disposed between the organic absorber layer and one of the first electrode or the second electrode. The term “charge blocking layer” as used herein refers to a layer capable of suppressing injection of a charge from the first electrode or the second electrode into the organic absorber layer upon application of a voltage across the pair of electrodes. In some embodiments, the charge blocking layer is an electron blocking layer, that is, a layer capable of blocking electrons and transporting holes. In certain embodiments, the charge blocking layer is a hole blocking layer, that is, a layer capable of blocking holes and transporting electrons.

The charge blocking includes a metal fluoride. The metal fluoride includes lithium, sodium, potassium, rubidium, cesium, beryllium, magnesium, calcium, strontium, barium, iron, yttrium, ytterbium, or combinations thereof. Non-limiting examples of suitable metal fluorides include lithium fluoride, magnesium fluoride, calcium fluoride, barium fluoride, sodium fluoride, potassium fluoride, or combinations thereof. In certain embodiments, the charge blocking layer includes lithium fluoride.

As mentioned previously, the charge blocking layer is substantially free of an electrically conductive material. The term “electrically conductive material” as used herein refers to a material having a volume resistivity that is less than about 10⁸ ohm-cm. The term “substantially free of electrically conductive material” as used herein means that the amount of electrically conductive material in the charge blocking layer is less than about 5 weight percent. In some embodiments, the amount of electrically conductive material in the charge blocking layer is less than about 1 weight percent.

Without being bound by any theory, it is believe that incorporating electrically conductive materials in a substantial amount in the charge blocking layer may not be desirable. For instance, mixing metals such as lithium, calcium or cesium (which are commonly used in OLEDs) with the metal fluoride in the charge blocking layer may result in moisture and oxygen sensitivity, thereby reducing the device stability and increasing fabrication complexity and cost. Further, incorporating inert metals such as silver or gold in the charge block layer may result in lower charge blocking effect as the metals may not possess preferential charge blocking for holes or electrons. Incorporating conductive organic materials may also result in reducing the device stability as organic materials are generally not miscible with inorganic metal fluorides, which could lead to undesirable phase separation, especially under high temperature field conditions and highly accelerated testing conditions.

In some embodiments, the charge blocking layer consists essentially of the metal fluoride. The term “consists essentially of” as used herein means that the charge blocking layer includes less than 5 weight percent of a material that may significantly alter its properties (e.g., charge transporting properties). As noted earlier, the charge blocking layer is substantially free of an electrically conductive material. The charge blocking layer may however include additional additives, dopants, and the like. For example, the charge blocking layer may include one or more dopants in additional to the metal fluoride. Similarly, the charge blocking layer may one or more additional species that may be incorporated into the charge blocking layer during one or more post-deposition process step (e.g, the electrode deposition step)

Further, the thickness of the charge blocking layer is greater than about 10 nanometers. In some embodiments the thickness of the charge blocking layer is in a range from about 10 nanometers to about 200 nanometers. In some embodiments, the thickness of the charge blocking layer is in a range from about 50 nanometers to about 100 nanometers. Without being bound by any theory, it is believed that that the thickness greater than 10 nanometers is desirable to provide the required stability (e.g., oxygen stability).

Without being bound by any theory it is believed that the incorporation of the metal-fluoride leakage charge blocking layer may provide not only reduced leakage current but also unexpected improved stability against exposure to air (or oxygen). The thickness required for stability improvement is substantially thicker than the normal thickness range useful for known OLED and OPV applications.

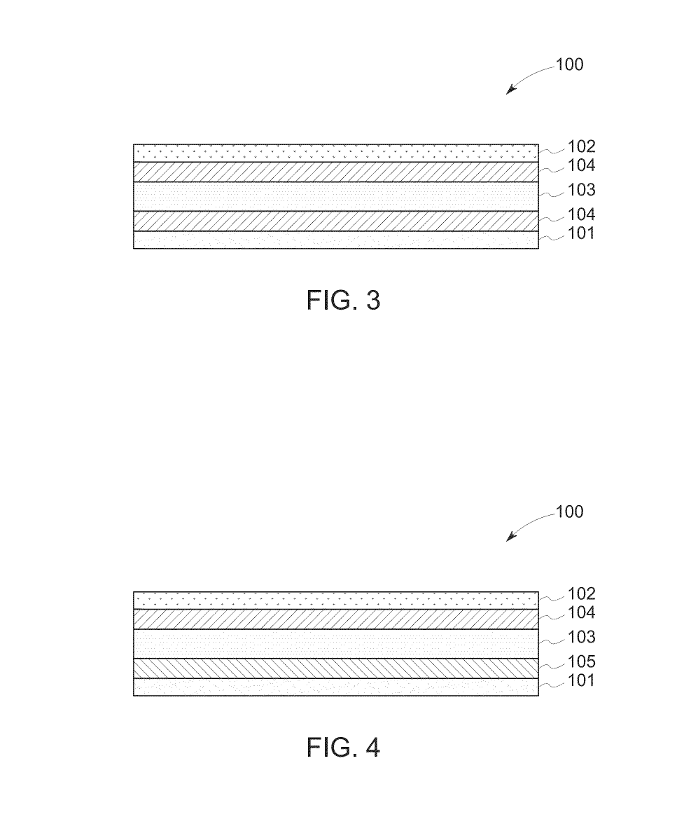

Referring now to FIGS. 1-3, the various configurations for the organic photodiode 100 are illustrated. In FIG. 1, the first charge blocking layer 104 is disposed between the second electrode 102 (for example, a cathode) and the organic absorber layer 103. Alternatively, in FIG. 2 the first charge blocking layer 104 is disposed between the first electrode (for example, an anode) 101 and the organic absorber layer 103. FIG. 3 illustrates an embodiment in which the first charge blocking layer 104 is disposed between the first electrode 101 and the organic absorber layer 103, and also between the second electrode 102 and the organic absorber layer 103.

In certain embodiments, the organic photodiode may further include a second charge blocking layer. FIG. 4 illustrates an embodiment including a first charge blocking layer disposed between the second electrode 102 and the absorber layer 103; and a second charge blocking layer 105 disposed between the first electrode 101 and the organic absorber layer 103. In some embodiments, the charge blocking layer is a hole blocking layer, that is, a layer capable of blocking holes and transporting electrons. In certain embodiments, the charge blocking layer is an electron blocking layer, that is, a layer capable of blocking electrons and transporting holes.

The second charge blocking layer may include an organic material in some embodiments. Non-limiting examples of suitable materials for the second charge blocking layer include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyarylene compound, a condences aromatic hydrocarbon ring compound (a naphthalene derivative, an anthracene derivative, a phenanthrene derivative, a tetracene derivative, a pyrene derivative, a perylene derivative, or a fluoranthene derivative), or combinations thereof.

Some specific examples of suitable materials for the second charge blocking layer include aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (α-NPD); oxazole, oxadiazole, triazole, imidazole, and imidazolone; stilbene derivatives; pyrazoline derivatives; tetrahydroimidazole; polyarylalkane; butadiene; 4,4′,4″-tris(N-(3-methylphenyl)-N-phenylamino)triphenylamine (m-MTDATA); porphyrine compounds such as porphine, copper tetraphenylporphine, phthalocianine, copper phthalocyanine, and titanium phthalocyanine oxide; triazole derivatives; oxadiazole derivatives; imidazole derivatives; polyarylalkane derivatives; pyrazoline derivatives; pyrazolone derivatives; phenylenediamine derivatives; amino-substituted chalcone derivatives; oxazole derivatives; styrylanthracene derivatives; fluorenone derivatives; hydrazone derivatives; silazane derivatives; polymers of phenylenevinylene, fluorine, carbazole, indole, pyrene, pyrrole, picoline, thiophene, acetylene, diacetylene; or combinations thereof.

A method of forming an organic photodiode is also presented. Referring again to FIGS. 1-4, the method includes disposing an organic absorber layer 103 on a first electrode 101; disposing a second electrode 102 on the organic absorber layer 103; and disposing a first charge blocking layer 104 including a metal fluoride between the organic absorber layer and one of the first electrode or the second electrode. As noted earlier, the first charge blocking layer 104 is substantially free of an electrically conductive material, and the thickness of the charge blocking layer is greater than about 10 nanometers.

In some embodiments, the method may include disposing the first charge blocking layer 104 on the organic absorber layer 103; and disposing the second electrode 102 on the first charge blocking layer 104, as shown in FIG. 1. In some such instances, the second electrode 102 may be deposited on the first charge blocking layer 104 by sputtering. The second electrode 102 may include a substantially transparent conductive oxide in such instances. As shown in FIG. 4, the method may further include disposing a second charge blocking layer 105 on the first electrode 101 and disposing the organic absorber layer on the second charge blocking layer 105 before the step of disposing the first charge blocking layer 104 on the absorber layer, in some embodiments.

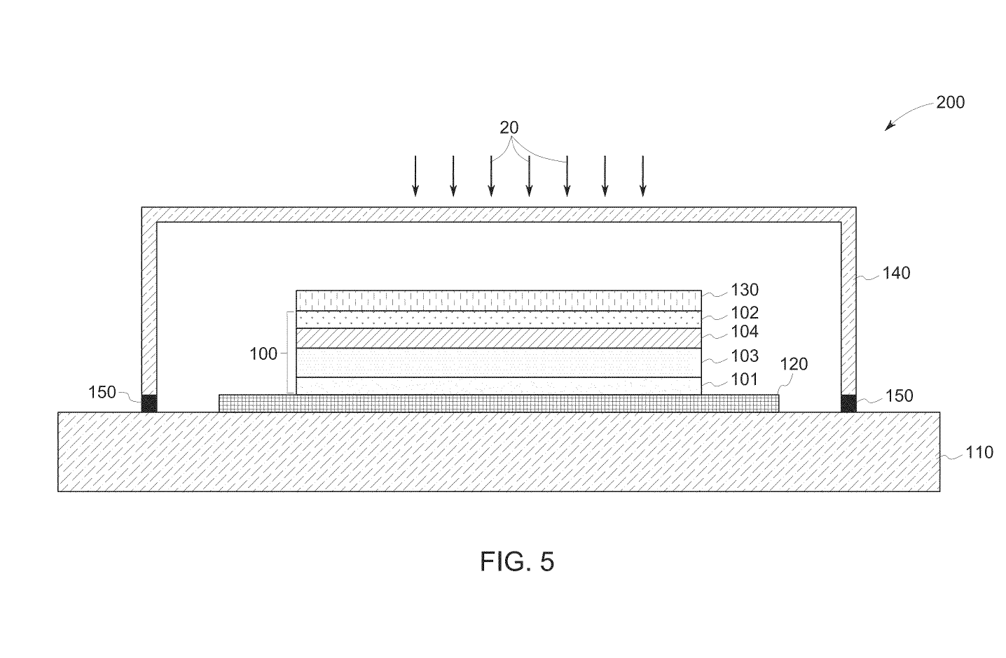

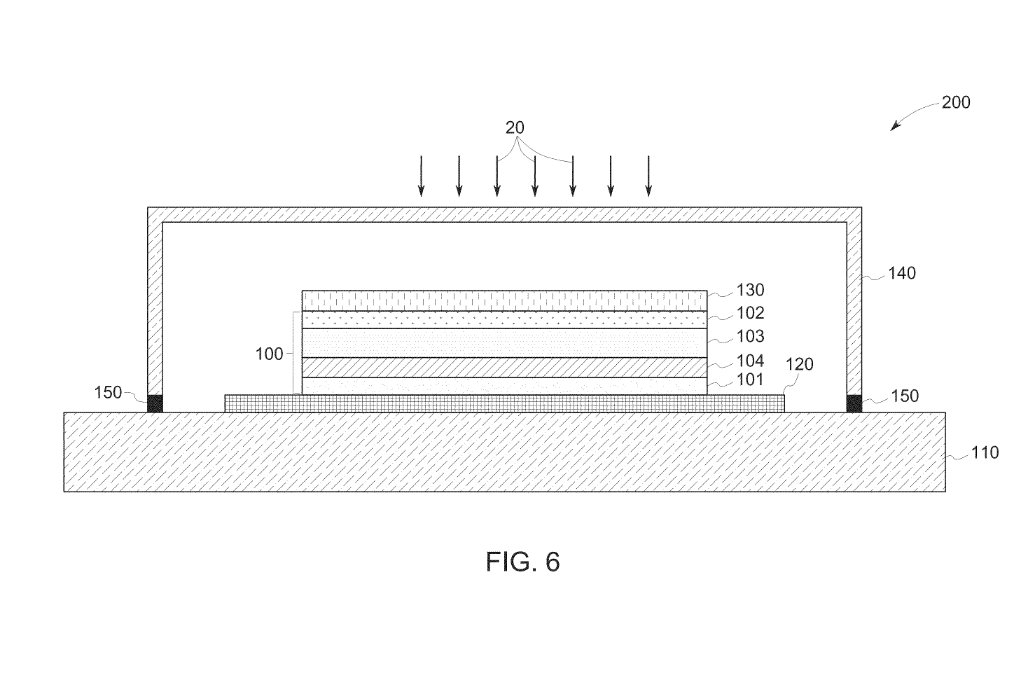

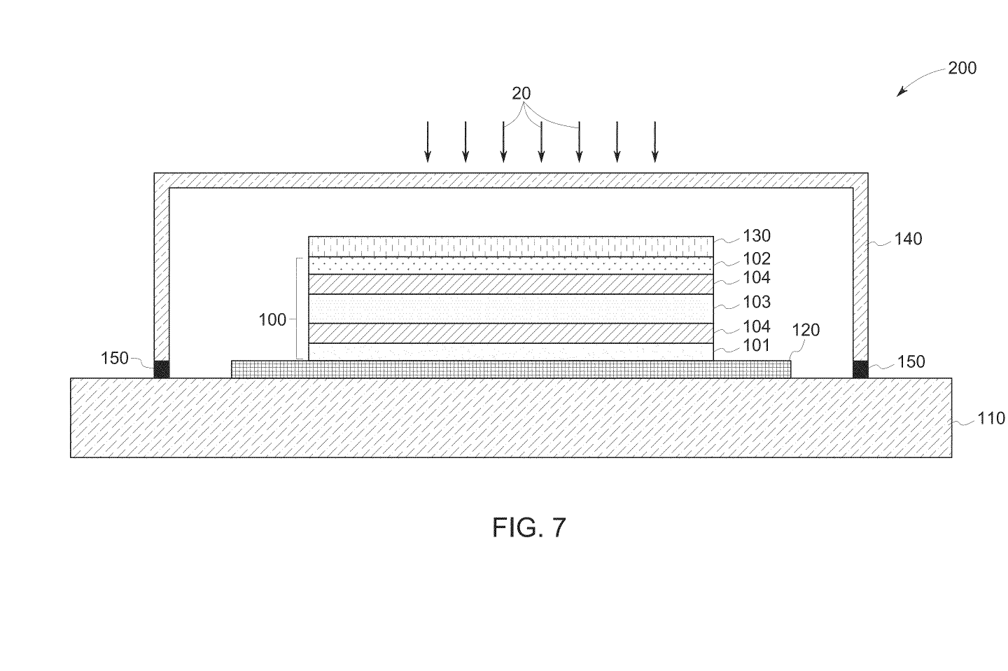

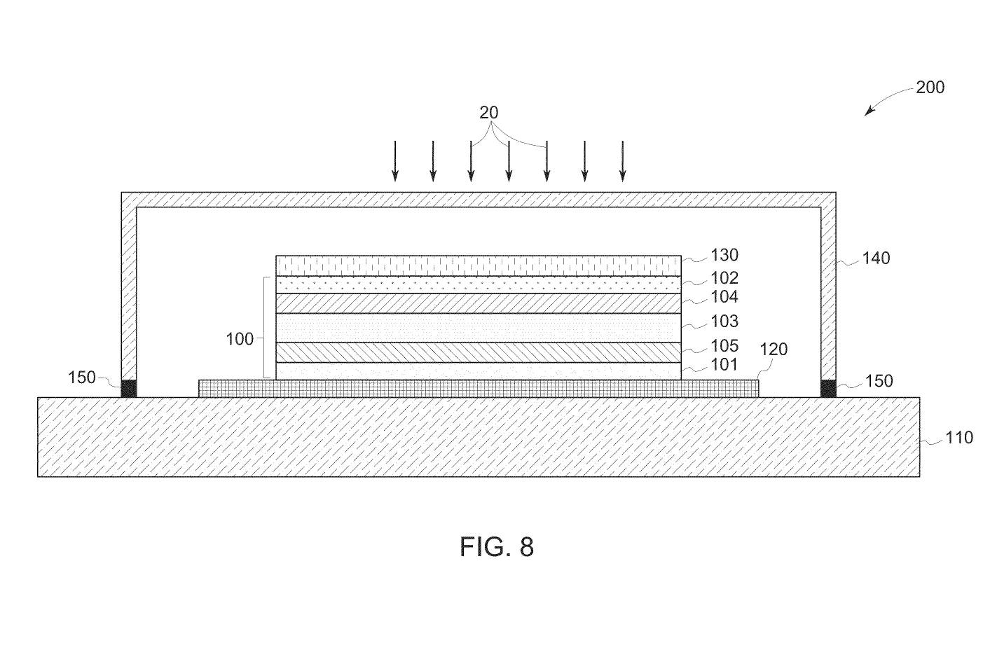

In some embodiments, an organic x-ray detector (OXRD) is also presented. A schematic representation of such an organic x-ray detector is shown in FIGS. 5-8. An organic x-ray detector 200 includes a thin-film transistor (TFT) array 120 disposed on a substrate 110, an organic photodiode 100 disposed on the TFT array 120, and a scintillator layer 130 disposed on the organic photodiode 100. FIGS. 5-8 illustrate the various configurations for the first charge blocking layer 104 in the organic photodiode 100, as described earlier.

The photodiode 100 may be directly disposed on the TFT array 120 or the design may include one or more layers disposed between the photodiode 100 and the TFT array 120. As illustrated in FIGS. 5-8, the scintillator layer 130 is excited by impinging x-ray radiation 20 and produces visible light. Scintillator layer 130 may be composed of a phosphor material that is capable of converting x-rays to visible light. The wavelength region of light emitted by scintillator layer 130 may range from about 360 nm to about 830 nm. Suitable materials for the layer include, but are not limited to, cesium iodide (CsI), CsI (Tl) (cesium iodide to which thallium has been added) and terbium-activated gadolinium oxysulfide (GOS). Such materials are commercially available in the form of a sheet or screen. Another scintillator that may be used is a PIB (particle in binder) scintillator, where scintillating particles may be incorporated in a binder matrix material and flattened on a substrate. The scintillator layer 130 may be a monolithic scintillator or pixelated scintillator array. The visible light generated by the scintillator layer 130 irradiates an organic photodiode 100 disposed on a TFT array 120.

Referring again to FIGS. 5-8, the TFT array 120 may be a two dimensional array of passive or active pixels, which stores charge for read out by electronics, disposed on an active layer formed of amorphous silicon or an amorphous metal oxide, or organic semiconductors. In some embodiments, the TFT array includes a silicon TFT array, an oxide TFT array, an organic TFT, or combinations thereof. Suitable amorphous metal oxides include zinc oxide, zinc tin oxide, indium oxides, indium zinc oxides (In—Zn—O series), indium gallium oxides, gallium zinc oxides, indium silicon zinc oxides, and indium gallium zinc oxides (IGZO). IGZO materials include InGaO₃(ZnO)ₘ where m is <6) and InGaZnO₄. Suitable organic semiconductors include, but are not limited to, conjugated aromatic materials, such as rubrene, tetracene, pentacene, perylenediimides, tetracyanoquinodimethane and polymeric materials such as polythiophenes, polybenzodithiophenes, polyfluorene, polydiacetylene, poly(2,5-thiophenylene vinylene), poly(p-phenylene vinylene) and derivatives thereof.

The TFT array 120 is further disposed on a substrate 110. Suitable substrate 110 materials include glass, ceramics, plastics and metals. The substrate 110 may be present as a rigid sheet such as a thick glass, a thick plastic sheet, a thick plastic composite sheet, and a metal plate; or a flexible sheet, such as, a thin glass sheet, a thin plastic sheet, a thin plastic composite sheet, and metal foil. Examples of suitable materials for the substrate include glass, which may be rigid or flexible; plastics such as polyethylene terephthalate, polybutylene phthalate, polyethylene naphthalate, polystyrene, polycarbonate, polyether sulfone, polyallylate, polyimide, polycycloolefin, norbornene resins, and fluoropolymers; metals such as stainless steel, aluminum, silver and gold; metal oxides such as titanium oxide and zinc oxide; and semiconductors such as silicon. In one particular embodiment, the substrate includes a polycarbonate.

As shown in FIGS. 5-8, the scintillator layer 130, the photodiode 110, and the TFT array 120 are enclosed inside an encapsulation cover 140 to protect them from the moisture and oxygen introduced from the atmosphere. In some embodiments, one or more additional seals 150 may be provided to provide effective sealing between the encapsulation cover 140 and the substrate 110.

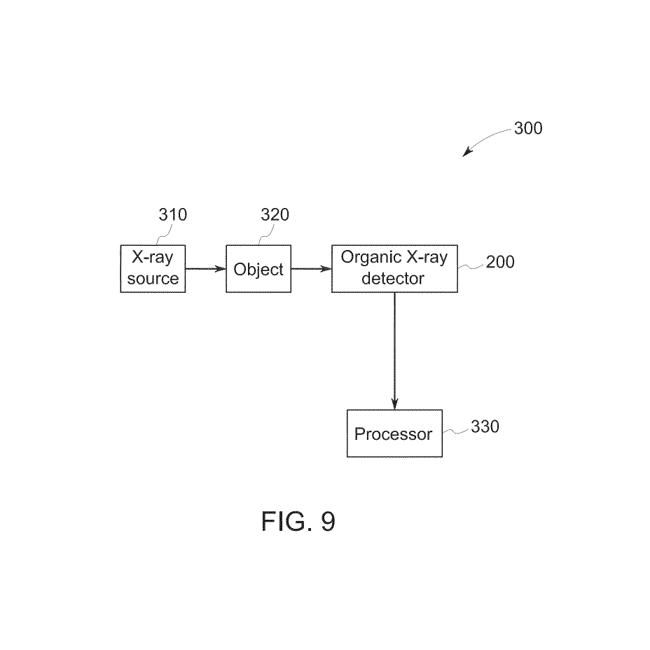

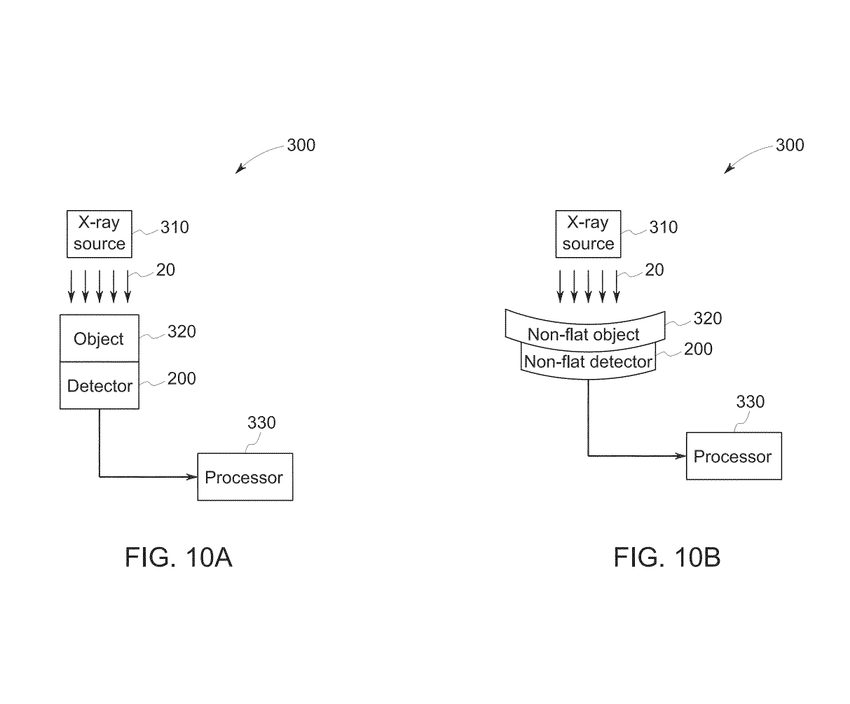

In some embodiments, an x-ray system is also presented. As shown in FIG. 9, the x-ray system 300 includes an x-ray source 310 configured to irradiate an object 320 with x-ray radiation, an organic x-ray detector 200 as described earlier, and a processor 330 operable to process data from the organic x-ray detector 200. FIGS. 10A and 10B further show embodiments of the x-ray system 300 suitable for substantially flat objects or objects with a curved shape. As shown in FIGS. 10A and 10B, the x-ray detector 200 may have a shape suitable for the object 320. In FIGS. 10A and 10B, the controller 330 may be communicatively coupled to the x-ray detector 200 using a wired or a wireless connection.

An x-ray detector according to embodiments of the present invention may be used in imaging systems, for example, in conformal imaging, with the detector in intimate contact with the imaging surface. For parts with internal structure, the detector may be rolled or shaped to contact the part being imaged. Applications for the organic x-ray detectors according to embodiments of the present invention include security imaging; medical imaging; and industrial and military imaging for pipeline, fuselage, airframe and other tight access areas.

### EXAMPLES

### Comparative Example 1

### OLED Performance as a Function of LiF Thickness

Poly(3,4-ethylenedioxythiophene) doped with polystyrene sulfonate (PEDOT:PSS) was purchased from Bayer Corporation under the trade name Baytron® P. A blue light-emitting polymer (ADS329BE) was obtained from American Dye Source, Inc, Quebec, Canada. Lithium fluoride (≧99%) was purchased from Aldrich and used as received. Seven organic light-emitting devices (OLEDs) were fabricated as follows.

Glass pre-coated with ITO was used as the substrate. A 80 nm layer of PEDOT:PSS was deposited onto ultraviolet-ozone treated ITO substrates via spin-coating and then baked for 1 hour at 180° C. in air. A layer of ADS329BE, as the emissive layer, was then spin-coated atop the PEDOT:PSS layer inside a N₂ purged glovebox. The emissive layer had a thickness of 70 nm, as determined by mechanical profilometry. A layer of LiF of varying thicknesses was applied on top of the emissive layer. The device fabrication was completed with evaporation of Al cathode. The device performance was characterized by measuring current-voltage-luminance (I-V-L) characteristics and electroluminescence spectra. A photodiode calibrated with a luminance meter (Minolta LS-110) was used to measure the luminance (in units of candela per square meter, cd/m²).

Table 1 shows the performance for OLEDs with and without LiF. The driving voltage for a fixed current density decreased significantly and light intensity increased dramatically when an ultrathin layer of LiF (e.g., ˜1 nm) was added between the emissive layer and the Al cathode. Further increasing the LiF thickness degraded the OLED performance as the driving voltage increased substantially and emission was not discernible when LiF thickness was greater than 10 nm.

TABLE 1
OLED performance as a function of LiF thickness

| | Voltage at | |
|---|---|---|
| LiF thickness | 2.5 mA/cm² | Brightness at 2.5 mA/cm² |
| (nm) | (V) | (cd/m²) |
| 0 | 9.2 | 0.21 |
| 0.6 | 5.5 | 55.7 |
| 1.2 | 5.4 | 94.2 |
| 2.3 | 5.8 | 67.1 |
| 4.6 | 8.1 | 7.9 |
| 11.6 | 14.1 | 0.03 |
| 23.2 | 28.0 | <0.01 |

### Example 1

### Organic Photodiodes with and without LiF

In this example, three donor polymers PCDTBT, PTB7 and P3HT were obtained from 1-Materials, Inc, Quebec, Canada. Lithium fluoride (≧99%) was purchased from Aldrich and used as received. Three organic photodiodes (OPDs) were fabricated as follows:

Glass pre-coated with ITO was used as the substrate. An 80 nm layer of hole-transporting layer (HTL) was deposited onto ultraviolet-ozone treated ITO substrates via spin-coating and then baked for 1 hour at 180° C. in air. An absorber layer consisting of a donor polymer and a fullerene based acceptor was then spin-coated atop the HTL layer inside of a N₂ purged glovebox. A LiF layer of 20 nm thickness was applied on top of the organic absorber layer. The device fabrication was completed with ITO sputtering. Three control OPDs were fabricated in the similar manner with the exception of LiF layer deposition. The device performance was characterized by measuring current-voltage (I-V) characteristics.

Table 2 summarizes the results for OPDs fabricated with and without the LiF layers. For all the three donor materials tested, the devices including a 20 nm LiF layer performed similarly as the device without the LiF layer.

TABLE 2
Performance of OPDs with and without LiF

| | | | Dark | Light |
|---|---|---|---|---|
| | | LiF thickness | current @−1 V | current @−1 V |
| Sample | Donor | (nm) | (A/cm²) | (A/cm²) |
| Control | P3HT | 0 | 1.19E−8 | 3.68E−8 |
| Sample 1 | | | | |
| Sample 1 | P3HT | 20 | 1.27E−8 | 4.29E−8 |
| Control | PCDTBT | 0 | 2.62E−12 | 8.24E−6 |
| Sample 2 | | | | |
| Sample 2 | PCDTBT | 20 | 1.01E−11 | 4.32E−6 |
| Control | PTB7 | 0 | 1.41E−9 | 4.79E−7 |
| Sample 3 | | | | |
| Sample 3 | PTB7 | 20 | 6.91E−11 | 6.8E−7 |

### Example 2

### Organic Photodiode Stability for Devices with and without LiF

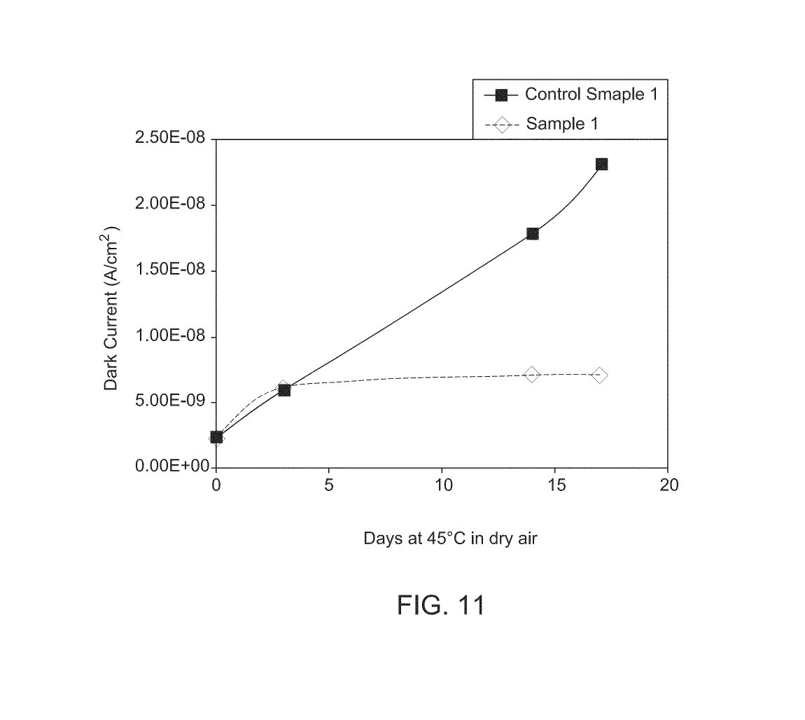

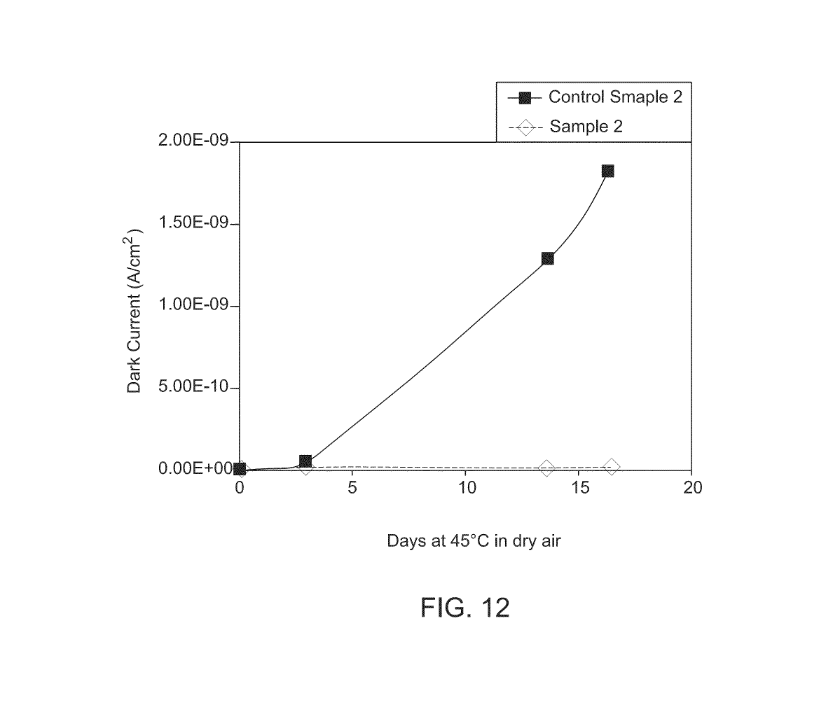

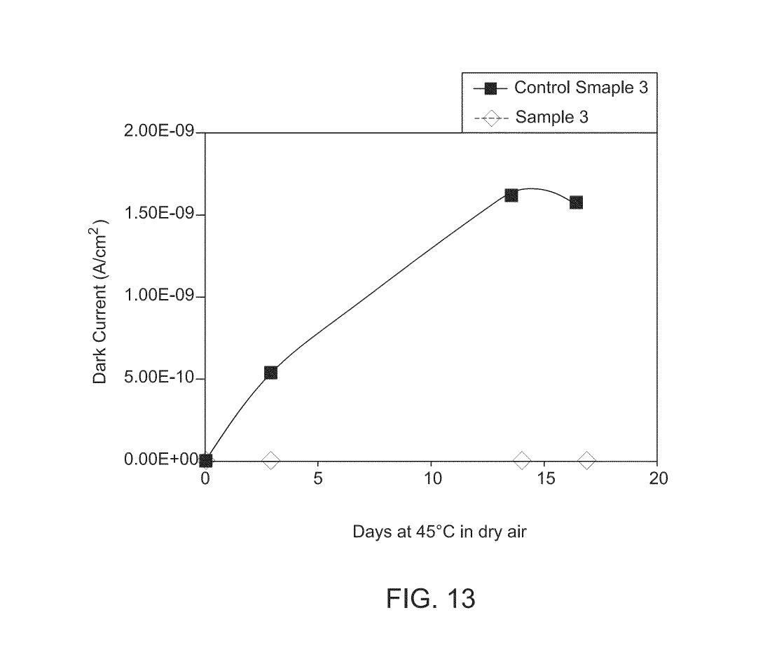

The OPD devices fabricated in Example 1 were stored in a testing chamber filled with dry air at 45° C. The dark current measurements were conducted for time to time, and are shown in FIGS. 11-13. As seen in FIGS. 11-13, the devices with LiF (Samples 1-3) exhibited a much smaller change in dark current over a period of time when compared to the devices without any LiF (Control Samples 1-3).

### Example 3

### Stability of Organic X-Ray Detectors with and without LiF

Three organic x-ray imagers based on the organic photodiode (OPD) technology were fabricated as follows:

Glass based thin-film-transistor (TFT) array pre-coated with ITO was used as the substrate. A hole-transport layer (HTL) was deposited onto ultraviolet-ozone treated TFT array substrates via spin-coating and then baked on a hotplate. An absorber layer consisting of a fullerene based acceptor and a donor material was then spin-coated atop the HTL layer inside of a N₂ purged glovebox. A LiF layer of two different thickness values (8 nm and 20 nm) was applied on top of the organic absorber layer. The imager fabrication was completed with ITO sputtering. The device performance was characterized using an imager functional tester. A control imager was fabricated in a similar fashion except for the deposition of the LiF layer.

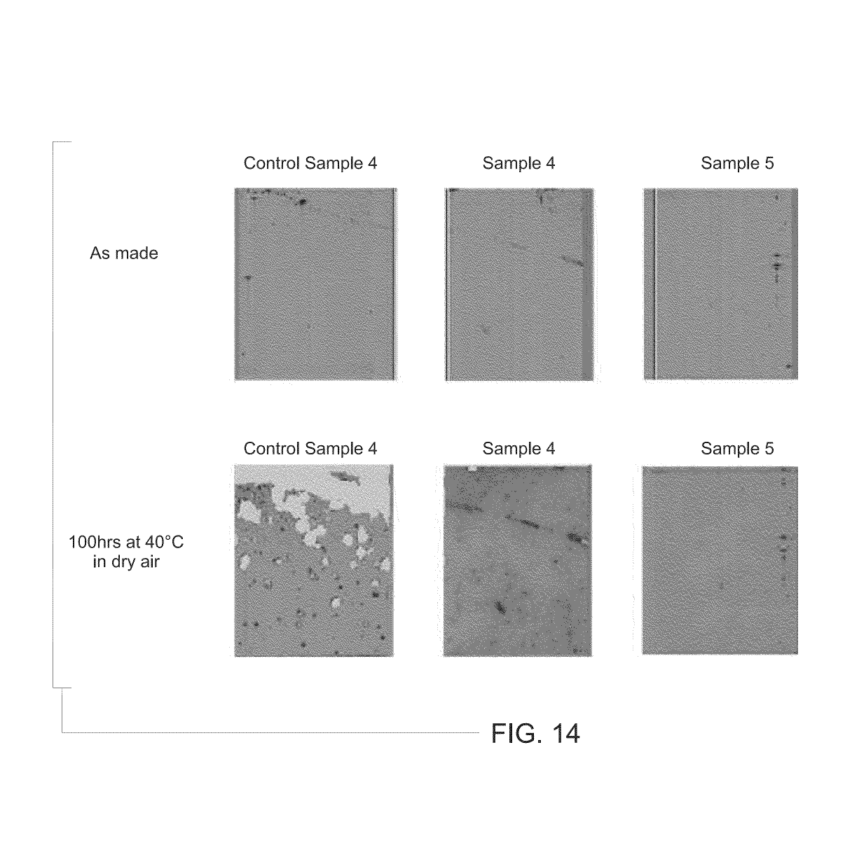

FIG. 14 shows the defect maps of the three imagers after exposing to dry air at 40° C. for 100 hours. FIG. 14 shows defects maps for three imagers: control Sample 4 (no LiF); Sample 4 (8 nm LiF thickness); and Sample 5 (20 nm LiF thickness).

As shown in FIG. 14, the incorporation of LiF significantly improved imagers' stability against exposure to air (or oxygen). The control Sample 4 exhibited significant degradation and increased number of defects (highlighted as yellow) after 100 hour exposure to dry air. In comparison, the Sample 5 (20 nm LiF thickness) had no visible degradation upon exposure to dry air. The improved stability against air exposure was observed as a function of LiF thickness. It should be noted that the thickness required to achieve the stability improvement is substantially thicker than the thickness range (typically on the order of 1 nm or less) known in the art for OLED and OPV applications.

### Example 3

### Performance of Organic X-Ray Detectors as a Function of LiF Thickness

Four organic x-ray imagers based on the organic photodiode (OPD) technology were fabricated as described in Example 2. The LiF thickness was varied from 30 nm to 90 nm. A control imager was further fabricated without the LiF layer. Table 3 provides the normalized quantum efficiency (QE) for the four imagers. The imagers including the LiF layer (for all the thicknesses) showed higher quantum efficiency when compared to the imager without the LiF layer.

TABLE 3
Performance of organic X-ray detector imagers as a
function of LiF thickness

| LiF thickness (nm) | Normalized QE |
|---|---|
| 0 | 100% |
| 30 | 121% |
| 60 | 131% |
| 90 | 114% |

The foregoing examples are merely illustrative, serving to exemplify only some of the features of the invention. The appended claims are intended to claim the invention as broadly as it has been conceived and the examples herein presented are illustrative of selected embodiments from a manifold of all possible embodiments. Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

1. An organic photodiode, comprising:
a first electrode;
an organic absorber layer disposed on the first electrode;
a second electrode disposed on the organic absorber layer; and
a first charge blocking layer comprising a metal fluoride disposed between the organic absorber layer and one of the first electrode or the second electrode, wherein the metal fluoride comprises lithium, sodium, potassium, rubidium, cesium, berrylium, magnesium, calcium, strontium, barium, iron, yttrium, ytterbium, or combinations thereof, wherein the charge blocking layer is substantially free of an electrically conductive material, and wherein the thickness of the charge blocking layer is greater than about 10 nanometers.

2. The organic photodiode of claim 1, wherein the first charge blocking layer consists essentially of the metal fluoride.

3. The organic photodiode of claim 1, wherein the metal fluoride comprises lithium fluoride, magnesium fluoride, calcium fluoride, barium fluoride, sodium fluoride, potassium fluoride, or combinations thereof.

4. The organic photodiode of claim 1, wherein the first charge blocking layer has a thickness in a range from about 10 nanometers to about 200 nanometers.

5. The organic photodiode of claim 1, wherein the first charge blocking layer is disposed between the organic absorber layer and the second electrode, and the organic photodiode further comprises a second charge blocking layer disposed between the organic absorber layer and the first electrode.

6. The organic photodiode of claim 5, wherein the second charge blocking layer comprises an organic material.

7. The organic photodiode of claim 5, wherein the second electrode comprises a sputtered substantially transparent oxide.

8. A method of forming an organic photodiode, comprising:
disposing an organic absorber layer on a first electrode;
disposing a second electrode on the organic absorber layer; and
disposing a first charge blocking layer comprising a metal fluoride between the organic absorber layer and one of the first electrode or the second electrode, wherein the metal fluoride comprises lithium, sodium, potassium, rubidium, cesium, beryllium, magnesium, calcium, strontium, barium, iron, yttrium, ytterbium, or combinations thereof, wherein the charge blocking layer is substantially free of an electrically conductive material, and wherein the thickness of the charge blocking layer is greater than about 10 nanometers.

9. The method of claim 8, wherein the charge blocking consists essentially of the metal fluoride.

10. The method of claim 8, wherein the metal fluoride lithium fluoride, magnesium fluoride, calcium fluoride, barium fluoride, sodium fluoride, potassium fluoride, or combinations thereof.

11. The method of claim 8, wherein the first charge blocking layer has a thickness in a range from about 10 nanometers to about 200 nanometers.

12. The method of claim 8, comprising disposing the first charge blocking layer on the organic absorber layer; and disposing the second electrode on the first charge blocking layer by sputtering.

13. The method of claim 12, further comprising disposing a second charge blocking layer on the first electrode and disposing the organic absorber layer on the second charge blocking layer.

14. An organic x-ray detector, comprising:
a thin-film transistor (TFT) array disposed on a substrate;
an organic photodiode disposed on the TFT array, wherein the organic photodiode comprises:
a first electrode;
an organic absorber layer disposed on the first electrode;
a second electrode disposed on the organic absorber layer; and
a first charge blocking layer comprising a metal fluoride disposed between the organic absorber layer and one of the first electrode or the second electrode, wherein the metal fluoride comprises lithium, sodium, potassium, rubidium, cesium, beryllium, magnesium, calcium, strontium, barium, iron, yttrium, ytterbium, or combinations thereof, wherein the charge blocking layer is substantially free of an electrically conductive material, and wherein the thickness of the charge blocking layer is greater than about 10 nanometers; and
a scintillator layer disposed on the organic photodiode.

15. The organic x-ray detector of claim 14, wherein the first charge blocking layer consists essentially of the metal fluoride.

16. The organic x-ray detector of claim 14, wherein the metal fluoride comprises lithium fluoride, magnesium fluoride, calcium fluoride, barium fluoride, sodium fluoride, potassium fluoride, or combinations thereof.

17. The organic x-ray detector of claim 14, wherein the first charge blocking layer has a thickness in a range from about 10 nanometers to about 200 nanometers.

18. The organic x-ray detector of claim 14, wherein the organic photodiode further comprises a second charge blocking layer disposed between the organic absorber layer and the first electrode, and wherein the first charge blocking layer is disposed between the organic absorber layer and the second electrode.

19. The organic x-ray detector of claim 18, wherein the second electrode comprises a sputtered substantially transparent oxide.

20. An x-ray system, comprising:
an x-ray source;
the x-ray detector of claim 14; and
a processor operable to process data from the x-ray detector.
